(19) United States
(12) Patent Application Publication
(10) Pub. No.: US 2009/0050910 A1
(43) Pub. Date: Feb. 26, 2009

(54) FLAT PANEL BASED LIGHT EMITTING DIODE PACKAGE STRUCTURE

(75) Inventor: TSUNG-TING SUN, TAIPEI HSIEN (TW)

Correspondence Address: ROSENBERG, KLEIN & LEE, 3458 ELLICOTT CENTER DRIVE-SUITE 101, ELLICOTT CITY, MD, 21043, US

(73) Assignee: EDISON OPTO CORPORATION, TAIPEI (TW)

(21) Appl. No.: 11/842,571

(22) Filed: Aug. 21, 2007

(51) Int. Cl. H01L 33/00

(52) U.S. Cl. 257/89; 257/E33.001

(57) ABSTRACT

The present invention discloses a flat panel based light emitting diode (LED) package structure. The package structure comprises a substrate, a plurality of first LED chips, a plurality of second LED chips and a protective layer. The first LED chips and the second LED chips are located on the substrate, and the second LED chips surround the first LED chips. The protective layer is for covering the first LED chips and the second LED chips. The protective layer has a first sub-structure and a plurality of second sub-structures, wherein the first sub-structure corresponds to the first LED chips, and the second sub-structures correspond to the plurality of second LED chips.

### FIELD OF THE INVENTION

The present invention relates to a LED package structure, and more particularly to a flat panel based LED package structure capable of enhancing the brightness of the LED.

### BACKGROUND OF THE INVENTION

Light Emitting Diode (LED) was developed in the laboratory at the end of 1950, and was made commercially available by HP in 1968. In the initial stage, LED was applied for a monochrome red lamp. After Nichia had a breakthrough with the blue LED technology in 1992, emitting multiple colors by LED became available and the brightness of the LED was also enhanced. Applications of LED were used in the daily life by ways of a variety of package forms, such as display and SMD.

LED utilizes the principle of conversion from electricity to light. A voltage is applied to 2 terminals, namely the positive and negative terminals, in a semiconductor. When a current passes the semiconductor and makes electrons and holes being driven to combine, certain amount of energy is released in the form of light. Depending on the materials used, the energy level may cause photons to generate light with different wavelengths.

To compare with the traditional light source, LED has at least the following advantages:

1. LED is smaller in size, and a variety of size may be used for design selection.
2. LED can bear high impact.
3. LED has low power loss.
4. Decrease in brightness of LED is slower.
5. LED has longer lifetime, approximately 50,000 to 100,000 hours.
6. LED has lower power consumption.
7. A full series of light emitting colors can be manufactured (from blue 460 nm to red 660 nm).
8. LED can be a white light source.
9. LED provides high power efficiency and products with great brightness.
10. RGB chips can be packaged together to form three in one chips.

Please refer to FIGS. 1A and 1B, which show a three-dimensional and a cross-sectional views of the conventional flat panel based LED package structure, respectively. The conventional flat panel based LED package structure 1 has a plurality of LED chips 12 located on a substrate 11, and a lens cover layer 13 for covering all LED chips 12. The package structure of the conventional flat panel based LED package structure 1 results in the diffuseness of light source and decrease of light passing rate that cause a disadvantage of insufficient magnitude of brightness. Therefore, a package structure where each LED chip is covered by a single cover layer is desired to develop.

Please refer to FIGS. 2A and 2B, which show a three-dimensional and a cross-sectional views of another conventional flat panel based LED package structure. In the conventional flat panel based LED package structure 2, a plurality of LED chips 22 is located on a substrate 21. The package structure 2 further has a plurality of lens cover layers 23 and each lens cover layer 23 corresponds to a single LED chip 22 respectively. Although the package structure 2 with LED chips 22 having the individual lens cover layer 23 can concentrate light, the manufacturing process of the package structure 2 is more complex and thus takes longer time to complete, as a result, the package structure 2 is easily damaged during the manufacturing process.

In view of the disadvantages mentioned above, the inventor provides a flat panel based LED package structure to improve the above disadvantages based on several years of research and development as well as experiments.

### SUMMARY OF THE INVENTION

One object of the present invention is to provide a flat panel based LED package structure so as to improve the brightness of the flat panel based LED.

In accordance with the object of the present invention, a package structure capable of enhancing the brightness of the flat panel based LED is provided. The package structure comprises a substrate, a plurality of first LED chips, a plurality of second LED chips and a protective layer. The plurality of first LED chips and the plurality of second LED chips are located on the substrate, and the second LED chips surround the first LED chips. The protective layer is for covering the first LED chips and the second LED chips. The protective layer has a first sub-structure and a plurality of second sub-structures, wherein the first sub-structure corresponds to the first LED chips, and the second sub-structures corresponds to the second LED chips.

As a result, the flat panel based LED package structure in accordance with the present invention can increase the light passing rate and thus enhance the brightness of the LED.

In order for the examiner to better understand the technical features and objects of the present invention, preferred embodiments as well as accompanying drawings are used to describe the present invention as follows.

### BRIEF DESCRIPTION OF THE DRAWINGS

The subject matter regarded as the invention is particularly pointed out and distinctly claimed in the concluding portion of the specification. Features and advantages of the present invention may best be understood by reference to the following detailed description with the accompanying drawings in which:

FIG. 1A is a three-dimensional view of the conventional flat panel based LED package structure.

FIG. 1B is a cross-sectional view of the conventional flat panel based LED package structure.

FIG. 2A is a three-dimensional view of another conventional flat panel based LED package structure.

FIG. 2B is a cross-sectional view of another conventional flat panel based LED package structure.

FIG. 3A is a three-dimensional view of a first preferred embodiment of the flat panel based LED package structure in accordance with the present invention.

FIG. 3B is a cross-sectional view of a first preferred embodiment of the flat panel based LED package structure in accordance with the present invention.

FIG. 4A is a three-dimensional view of a second preferred embodiment of the flat panel based LED package structure in accordance with the present invention.

FIG. 4B is a cross-sectional view of a second preferred embodiment of the flat panel based LED package structure in accordance with the present invention.

FIG. 5A is a three-dimensional view of a third preferred embodiment of the flat panel based LED package structure in accordance with the present invention.

FIG. 5B is a cross-sectional view of a third preferred embodiment of the flat panel based LED package structure in accordance with the present invention.

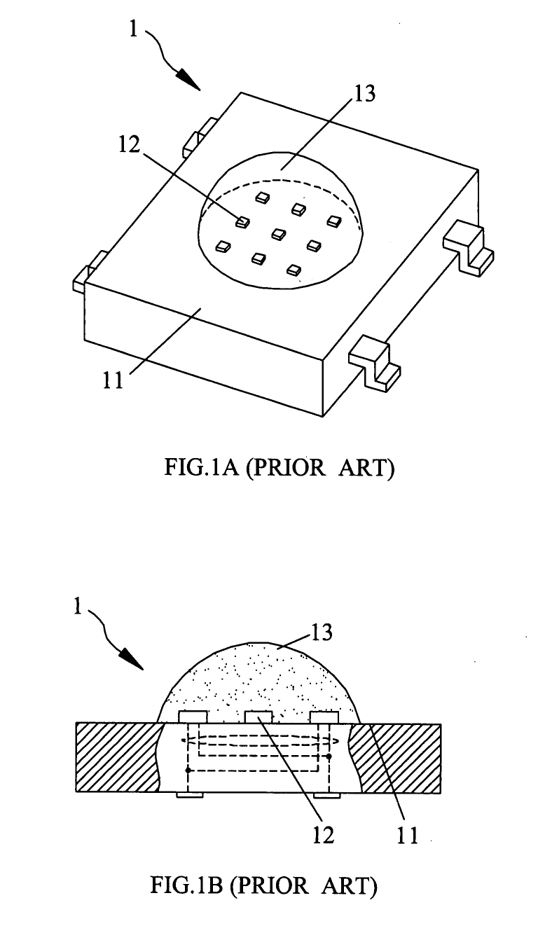

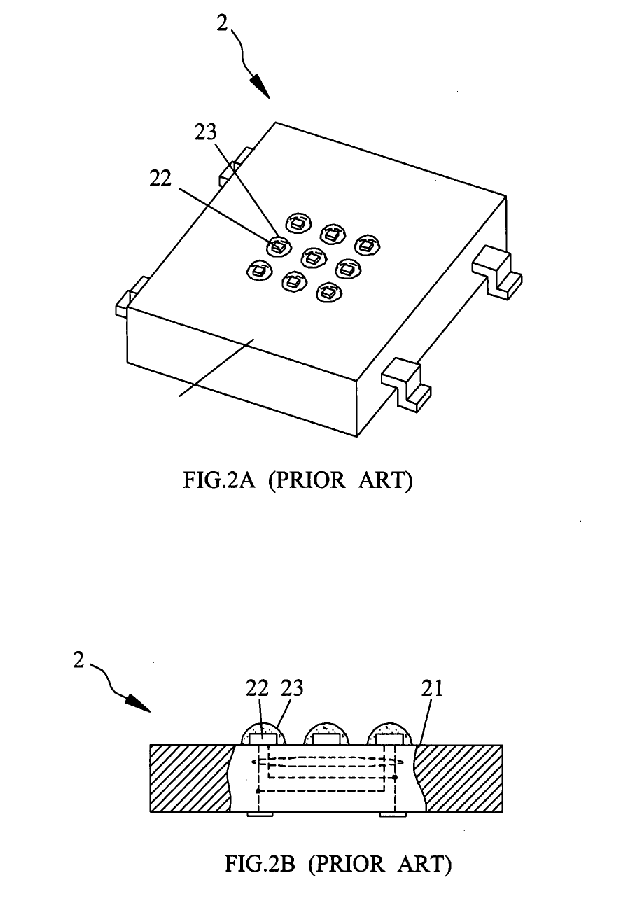

### DETAILED DESCRIPTION OF THE EMBODIMENTS

The flat panel based LED package structure in accordance with the present invention will now be described using preferred embodiments in reference to the accompanying drawings, where similar elements are indicated by similar reference numerals for ease of understanding.

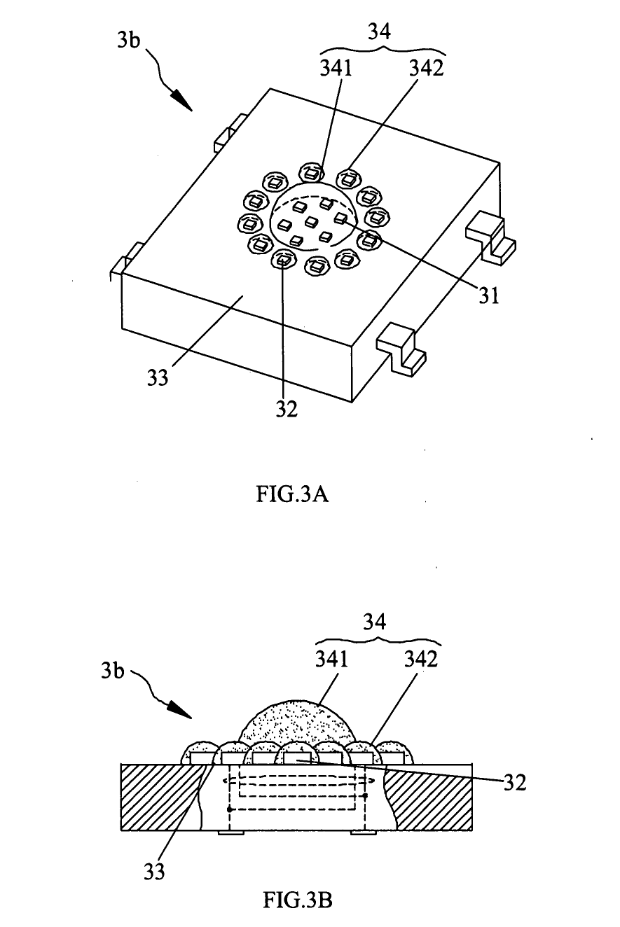

Please refer to FIGS. 3A and 3B, which show a three-dimensional and a cross-sectional views of the first preferred embodiment of the flat panel based LED package structure in accordance with the present invention, respectively. The flat panel based LED package structure 3 comprises a plurality of first LED chips 31, a plurality of second LED chips 32 and a substrate 33. The first LED chips 31 and the second LED chips 32 are located on the substrate 33. In the preferred embodiment, the first LED chips 31 and the second LED chips 32 are positioned in an axial/radial arrangement. Additionally, the second LED chips 32 surround the first LED chips 31. The first LED chip 31 and the second LED chip 32 can be a red LED chip, a blue LED chip, or a green LED chip.

The substrate 33 is used to reflect a light source generated by the first LED chips 31 and the second LED chips 32. In the preferred embodiment, the protective layer 34 has a first sub-structure 341 and a plurality of second sub-structures 342; wherein the first sub-structure 341 and the second sub-structures 342 on the surface of the protective layer 34 may be integrally formed. The protective layer 34 is for covering the first LED chips 31 and the second LED chips 32. The first sub-structure 341 corresponds to the first LED chips 31, and the second sub-structures 342 correspond to the second LED chips 32 respectively. In other words, the position of first sub-structure 341 corresponds to the first LED chips 31, and the position of each of the second sub-structures 342 correspond to one of the second LED chips 32 respectively. Each second LED chips 32 has the individual second sub-structures 342. Thus, at least one light emitted from the first LED chips 31 and the second LED chips 32 to the surface of the protective layer 34 is refracted and reflected by the first sub-structure 341 and the second sub-structures 342 on the surface of the protective layer, thereby the total internal reflection occurring on the surface of the protective layer 34 can be reduced. As a result, light passing rate is increased, and brightness of the flat panel based LED is also increased. Preferably, the protective layer 34 can be made of a transparent material such as epoxy, silicone, and glass.

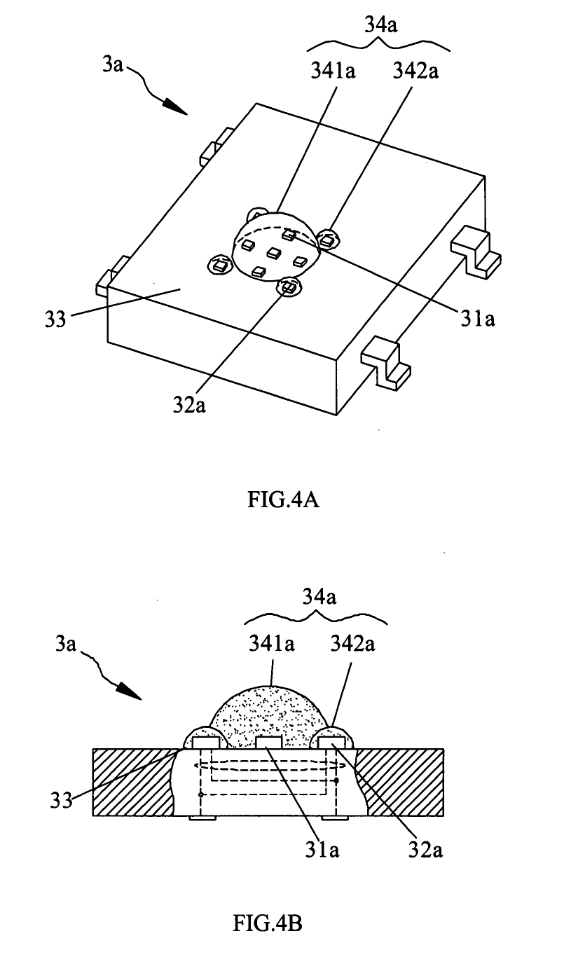

Please refer to FIGS. 4A and 4B, which show a three-dimensional and a cross-sectional views of the second preferred embodiment of the flat panel based LED package structure in accordance with the present invention, respectively. In the preferred embodiment, the protective layer 34a has a first sub-structure 341a and a plurality of second sub-structures 342a, wherein the first sub-structure 341a and the second sub-structures 342a located on the surface of the protective layer 34a may be integrally formed. The protective layer 34a is for covering the plurality of first LED chips 31a and the plurality of second LED chips 32a. In this embodiment, the first LED chips 31a are positioned in the center and the second LED chips 32a are positioned in the four corners respectively.

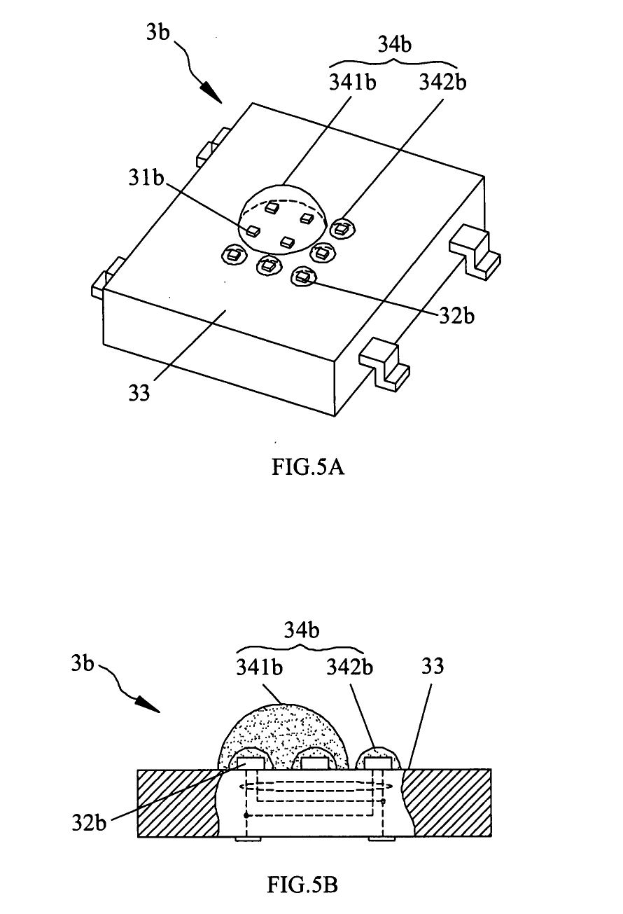

Please refer to FIGS. 5A and 5B, which show a three-dimensional and a cross-sectional views of the third preferred embodiment of the flat panel based LED package structure in accordance with the present invention, respectively. In this preferred embodiment, the protective layer 34b has a first sub-structure 341b and a plurality of second sub-structures 342b, wherein the first sub-structure 341b and the plurality of second sub-structures 342b located on the surface of the protective layer 34b may be integrally formed. The protective layer 34b is for covering the plurality of first LED chips 31b and the plurality of second LED chips 32b. The first LED chips 31b are positioned closer to one corner and surrounded by the second LED chips 32b.

The preferred embodiments mentioned above are intended for illustrative purpose only and are not meant to restrict the present invention. Any modifications or changes to the embodiments are within scope and spirit of the present invention. The scope of the present invention is set forth by the claims below.

What is claimed is:

1. A flat panel based light emitting diode (LED) package structure, comprising:
a substrate;
a plurality of first LED chips located on said substrate;
a plurality of second LED chips, located on said substrate and surrounding said plurality of first LED chips; and
a protective layer, covering said first LED chips and said second LED chips, and having a first sub-structure and a plurality of second sub-structures positioned on a surface of said protective layer, wherein said first sub-structure corresponds to said first LED chips, and each of said second sub-structures corresponds to one of said second LED chips respectively.

2. The package structure according to claim 1, wherein said first LED chips are positioned in an axial/radial arrangement.

3. The package structure according to claim 1, wherein said second LED chips are positioned in an axial/radial arrangement to surround said first LED chips.

4. The package structure according to claim 1, wherein said first LED chip and said second LED chip can be a red LED chip, a blue LED chip or a green LED chip.

5. The package structure according to claim 1, wherein said first sub-structure and said second sub-structures located on said surface of said protective layer are integrally formed.

6. The package structure according to claim 1, wherein said protective layer can be made of a transparent material such as epoxy, silicone or glass.

7. The package structure according to claim 1, wherein said substrate reflects a light source generated by said first LED chips and said second LED chips.
